(19) United States
(12) Patent Application Publication
(10) Pub. No.: US 2021/0249233 A1
(43) Pub. Date: Aug. 12, 2021

(54) PLASMA PROCESSING APPARATUS

(71) Applicant: Hitachi High-Tech Corporation, Minato-ku, Tokyo (JP)

(72) Inventors: Hiroyuki Kajifusa, Tokyo (JP); Kenetsu Yokogawa, Tokyo (JP); Takao Arase, Tokyo (JP); Masahito Mori, Tokyo (JP)

(21) Appl. No.: 16/980,501

(22) PCT Filed: Dec. 18, 2019
(86) PCT No.: PCT/JP2019/049535

§ 371 Date: Sep. 14, 2020

(51) Int. Cl. H01J 37/32; H01L 21/311

(52) U.S. Cl. CPC H01J 37/32642; H01J 37/32183; H01J 2237/334; H01L 21/31116; H01J 37/32568

(57) ABSTRACT

A plasma processing apparatus equipped with an electrode disposed inside a sample deck on which a wafer is mounted, the sample deck being disposed in the lower part within a processing chamber inside a vacuum container, the electrode being supplied with high frequency power during processing of the wafer, a ring-like member electrode made of a conductor disposed to surround the upper surface on the outer peripheral side of the sample deck, a first ring-like cover made of a dielectric body disposed to cover the ring-like member, and a second ring-like cover made of a conductor disposed to cover the first ring-like cover, and a controller that adjusts the magnitude of the high frequency power according to a result of detection of voltage of the high frequency power supplied to the ring-like member during processing of the wafer.

### TECHNICAL FIELD

The present invention relates to a plasma processing apparatus that processes a sample of a substrate shape such as a semiconductor wafer mounted on a sample deck arranged inside a processing chamber within a vacuum container using plasma, and relates to a plasma processing apparatus that processes a sample supplying high frequency power to the sample deck.

### BACKGROUND ART

In the manufacturing process of a semiconductor device, it is commonly executed to etch a film structure formed beforehand on a substrate of a semiconductor wafer. In the plasma processing apparatus in particular, it is allowed to form a perpendicular shape on the wafer by introducing a processing gas into a processing chamber and plasmatizing the processing gas, forming an electric field on the wafer by high frequency bias to attract charged particles such as the ion within the plasma to the wafer, and allowing the charged particles to be made incident on the wafer perpendicularly.

With respect to such plasma processing apparatus, it is required to process a wider range of the wafer surface more evenly from the requirement of improving the productivity of the semiconductor device. When the etching characteristic (processing rate for example) changes according to the location within the wafer surface, the shape after etching disperses according to the location within the wafer surface. As the dispersion becomes larger, a portion not satisfying the required shape increases, and the product yield drops. In the outer peripheral part of the wafer in particular, in attracting the charged particles to the wafer at the time of etching, incidence of the charged particles is concentrated by distortion of the electric field on the wafer, and tilting of the etching shape occurs.

Also, when a member arranged in the vicinity of the outer peripheral part of the wafer ablates by repetition of the plasma processing, the electric field distribution on the wafer changes according to the change in the shape of the member, and the degree of tilting also changes. Although replacement of the member is required in order to control tilting constant, it is necessary to stop the processing apparatus at that time. When frequent replacement of the member is required, the availability factor of the processing apparatus drops to increase the wafer processing cost, and therefore a processing apparatus not necessitating replacement of the member for a long time is required. Further, a technology of easily detecting ablation of a member from outside the apparatus is required in order to minimize the number of times of replacement of the member.

As a prior art for solving the problem described above, one disclosed in Japanese Unexamined Patent Application Publication No. 2011-108764 (Patent Literature 1) was known in the past. According to this prior art, there is disclosed one in which a focus ring made of a dielectric body and a focus ring made of a conductor are disposed to be overlaid on a focus ring made of a conductor that is made to have a same potential with the wafer, and temporal change of the edge electric field caused by ablation of the focus ring is suppressed.

Also, in Japanese Unexamined Patent Application Publication No. 2016-225376 (Patent Literature 2), there is disclosed: a method for detecting ablation of a member made of a dielectric body using the change in impedance of a circuit, in which a ring made of a conductor to which high frequency power can be applied and the member made of a dielectric body covering the ring is arranged so as to surround the outer peripheral side of a wafer; and a technology for controlling tilting by changing the magnitude of the power applied to the ring made of a conductor according to the ablation amount.

### CITATION LIST

### Patent Literature

Patent Literature 1: Japanese Unexamined Patent Application Publication No. 2011-108764

Patent Literature 2: Japanese Unexamined Patent Application Publication No. 2016-225376

### SUMMARY OF INVENTION

### Technical Problem

According to the prior arts described above, there were limitations in the method for electrically detecting ablation of a member disposed in the vicinity of the outer peripheral part of the wafer which may possibly affect the electric field of the outer peripheral part of the wafer.

According to the technology of Patent Literature 1, when the focus ring made of a conductor at the lowest part ablated, distribution of the equipotential plane was affected, and therefore it was required to detect this ablation. However, it was impossible in principle to electrically detect ablation of the focus ring at the lowest part.

Also, according to the technology of Patent Literature 2, it was found out that ablation of the inner side surface closest to the wafer of a member in the vicinity of the outer peripheral part of the wafer could not be detected independently, the ablation of the inner side surface affecting the electric field of the outer peripheral part of the wafer most strongly.

The object of the present invention is to provide a plasma processing apparatus that can secure stable plasma processing characteristics by more precisely detecting only ablation of a portion affecting control of the electric field in the vicinity of the outer peripheral part of the wafer most strongly.

### Solution to Problem

The object described above is achieved by a plasma processing apparatus including: a processing chamber in which plasma is generated, the processing chamber being disposed inside a vacuum container; a sample deck on which a wafer of an object of processing using the plasma is mounted, the sample deck being disposed in a lower part inside the processing chamber, the wafer being mounted on an upper surface of a projected part disposed at a center part of an upper part of the sample deck; an electrode that is supplied with high frequency power during processing of the wafer, the electrode being disposed inside the sample deck; a ring-like member made of a conductor disposed to surround the upper surface on an outer peripheral side of the projected part of the sample deck; a first ring-like cover made of a dielectric body disposed to oppose and cover the ring-like member between the ring-like member and the processing chamber and between the ring-like member and an upper surface of the sample deck; a second ring-like cover made of a conductor disposed to cover the first ring-like cover between the processing chamber and an upper surface of the first ring-like cover; and a controller that adjusts magnitude of high frequency power according to a result of detection of voltage of the high frequency power flowing through a power feeding passage that connects a high frequency power source and the ring-like member to each other, the high frequency power source supplying high frequency power to the ring-like member made of a conductor during processing of the wafer

### Advantageous Effects of Invention

According to the present invention, it is allowed to provide a plasma processing apparatus that can more precisely detect temporal change of the plasma processing characteristics in the outer peripheral part of the wafer.

### BRIEF DESCRIPTION OF DRAWINGS

FIG. 1 is a schematic view showing a shape formed by plasma processing of a wafer.

FIG. 2 is a vertical cross-sectional view enlargedly and schematically showing a configuration of a portion on the outer peripheral side of a sample deck in a plasma processing apparatus.

FIG. 3 is a vertical cross-sectional view enlargedly and schematically showing a configuration of a portion on the outer peripheral side of a sample deck in a plasma processing apparatus.

FIG. 4 is a vertical cross-sectional view schematically showing a configuration of a plasma processing apparatus related to an embodiment of the present invention.

FIG. 5 is a vertical cross-sectional view enlargedly and schematically showing a configuration of a portion on the outer peripheral side of a sample deck of the embodiment shown in FIG. 4.

FIG. 6 is a vertical cross-sectional view schematically showing a state after ablation of a member by plasma processing of the portion on the outer peripheral side of the sample deck shown in FIG. 5.

FIGS. 7A and 7B are cross-sectional views schematically showing a shape after a film having a predetermined thickness disposed on the surface of a wafer is subjected to an etching process.

FIGS. 8A and 8B are vertical cross-sectional views schematically showing an outline of a configuration of a prior art of a sample deck having a configuration for suppressing the temporal change.

FIGS. 9A and 9B are vertical cross-sectional views schematically showing a configuration of another modified example around a power source of a plasma processing apparatus related to an embodiment of the present invention.

### Description of Embodiments

Explanation will be made on the change in the distribution of the electric field and the etching characteristics in the outer peripheral part of the wafer.

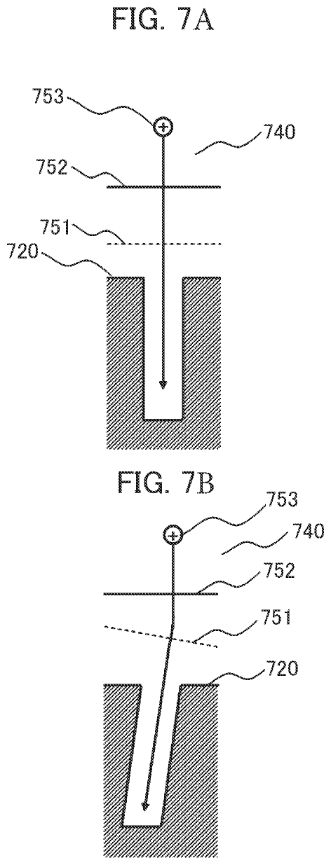

FIGS. 7A and 7B are cross-sectional views schematically showing a shape after a film having a predetermined thickness disposed on the surface of a wafer is subjected to an etching process.

FIG. 7A shows a state plasma 740 having predetermined potential is formed in a space above the upper surface of a wafer 720 and a sheath having a predetermined thickness is formed between the plasma 740 and the surface of the wafer 720 along the surface of the wafer 720. The reference sign 752 shows the boundary face of the sheath, and the thickness of the sheath formed between the sheath boundary face 752 and the upper surface of the wafer 720 (the distance between the sheath boundary face 752 and the upper surface of the wafer 720) changes according to the magnitude of the high frequency power supplied to an electrode below the wafer 720.

A charged particle 753 (having positive electric charge in the present drawing) in the plasma 740 receives a coulombic force in the electric field that is formed between the wafer 720 and the plasma 740, and is attracted and accelerated toward the wafer 720 in the direction perpendicular to an equipotential plane 751 in the sheath. As shown in FIG. 7A, when the equipotential plane 751 is parallel with the upper surface of the wafer 720, the charged particle 753 in the plasma is made to be incident and collides perpendicularly on a film on the surface of the wafer 720. With respect to the pattern such as a grove and hole formed by removing material of the film using a physical or chemical reaction utilizing the energy of the collision, the direction and the shape of the side wall surface of the pattern are made to be perpendicular to the upper surface of the film.

On the other hand, when the equipotential plane 751 inclines with respect to the upper surface of the wafer 720 as shown in FIG. 7B, the charged particle 753 comes to be incident obliquely with respect to the upper surface of the film of the wafer 720. With respect to the shape and direction of the pattern to be formed, inclination (tilting) is caused in the processed shape in the direction and shape of the side wall surface. In a portion in the vicinity of the outer peripheral edge of the wafer 720 in particular, concentration of the electric field is liable to occur, the equipotential plane 751 inclines with respect to the upper surface of the film of the wafer 720, tilting occurs, and dispersion of the direction and shape occurs with respect to the pattern in the center portion of the wafer 720.

In order to suppress such increase of the magnitude of the inclination and its dispersion of the pattern in a portion in the vicinity of the outer peripheral edge with respect to a portion on the center side of the wafer 720, such method has been executed from the past to supply the power for forming bias potential to a ring-like electric conductor or a member made of a semiconductor disposed to surround the wafer 720 in the outside of the outer peripheral edge of the wafer 720, and to form a sheath having a desired size above a separate member covering the ring-like member or above thereof to make the equipotential plane 751 of the sheath of the outer peripheral edge portion of the wafer 720. Such ring facing the plasma 740 is called a focus ring, and such ablation occurs that a member on the upper surface of the focus ring is scraped by collision of the charged particle 753 of the plasma 740 during processing of the wafer 720, is detached by interaction against the particles of the plasma 740, and so on. Therefore, such problem occurs that, accompanying increase of the processing number of sheets of the wafer 720 and the time therefor, the height of the equipotential plane 751 of the sheath formed above the upper surface of the ring changes, and the degree of tilting described above also changes.

In order to make the value of tilting within a desired permissible range, it is required to suppress temporal change of the degree of ablation of the member of the ring and so on, or to appropriately replace the ring member. Therefore, such function is required to detect the amount of ablation of the member in order to accurately grasp the timing for replacing the member of the ring.

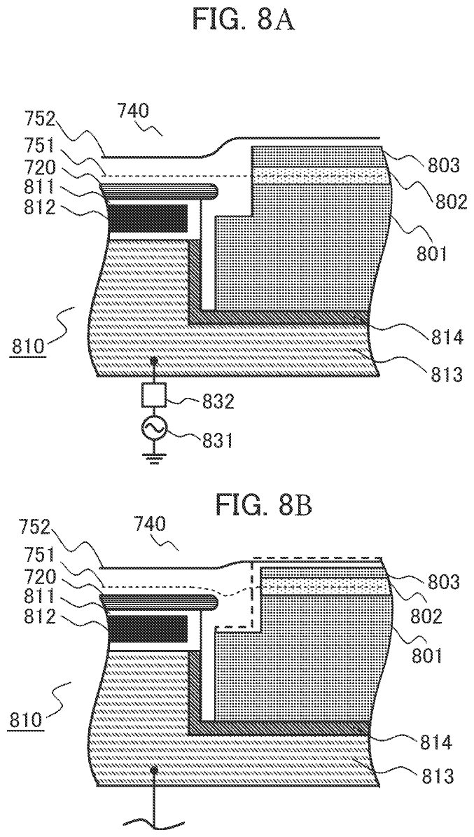

FIGS. 8A and 8B are vertical cross-sectional views schematically showing an outline of a configuration of a prior art of a sample deck having a configuration for suppressing the temporal change. FIG. 8A shows a state that a projected part having a cylindrical shape whose upper surface is elevated compared to the outer peripheral side is provided in the center portion of the upper part of a base material 813 made of a conductor such as a metal configuring an essential part of a sample deck 810 and having a cylindrical shape, a dielectric film 811 configured of a dielectric material such as the ceramics is disposed on the upper surface of the projected part, and the wafer 720 is mounted on the upper surface of the dielectric film 811. In this state, the wafer 720 is adsorbed and held by the upper surface of the dielectric film 811 by an electrostatic force that is formed by that electric power from a DC power source is supplied to a conductor film 812 which is a film-like electrode disposed inside the dielectric film 811.

The outer peripheral side of the projected part of the upper center part of the base material 813 is a recessed part whose upper surface height is lowered, the recessed part surrounding the projected part in a ring shape, a coated layer 814 is disposed on the surface of the side wall of the projected part having a cylindrical shape and the recessed part having the ring shape, the coated layer 814 being configured of a dielectric material such as the ceramics, and focus rings 801, 802, 803 which are ring-like members surrounding the projected part are disposed over the upper surface of the coated layer 813. These focus rings 801, 802, 803 are members stacked in the vertical direction, joined to each other, and configured as an integrated member, and are disposed on the recessed part so as to surround the wafer 720 on the outer peripheral side of the wafer 720 in a state the wafer 720 is mounted on and held by the dielectric film 811.

The base material 813 is electrically connected to a second high frequency power source 831 through a matching device 832, and high frequency power outputted by the high frequency power source 831 is supplied to the base material 813 while the wafer 720 is processed. With respect to the high frequency power, the focus ring 801 is electrically connected to the base material 813 and is made to have same potential with the base material 813. In this configuration, even when the shape of a sheath boundary face 152 namely the relative height position with respect to the upper surface of the wafer 720 for example may change accompanying that the focus ring 803 facing the plasma 740 ablates and the height of the upper surface lowers (fluctuates downward in the drawing), since ablation of the focus ring 802 caused by scraping and the like by the plasma 740 is less, fluctuation of distribution of the equipotential plane 751 inside a specific sheath positioned over a wafer 720 and inside the focus ring 802 is suppressed.

However, as exemplifying the shape before ablation in a broken line and the shape after ablation in a solid line in FIG. 8B, when the inner peripheral wall surface of the focus ring 801 disposed below ablates largely, the distance between the inner peripheral edge part of the focus ring 801 and the outer peripheral edge part of the wafer 720 comes to fluctuate in the horizontal direction (the left-right direction in the drawing), and distribution of an equipotential face 751 passing above the outer peripheral edge part of the wafer 720 and the inside of the focus ring 802 comes to change accompanying the fluctuation. Based on this fact, in order to suppress temporal change of the shape of the circuit pattern and distribution thereof with respect to the in-plane direction of the upper surface of the wafer 720 as a result of the etching process of the wafer 720, it is desirable to precisely detect the amount of the shape change caused by such ablation of the ring-like member disposed in the outer periphery of the wafer 720, to adjust the processing condition of the wafer 720 according to the detection result or to appropriately detect that the amount of the shape change has exceeded a predetermined permissible range, and to suppress delay of replacement of such member. On the other hand, the focus ring 801 positioned lowest is configured of metal or a semiconductor such as Si and is an electric conductor with respect to the high frequency power supplied through the base material 813, and it was hard to precisely detect the change in the supplied high frequency power even when the focus ring 801 ablates.

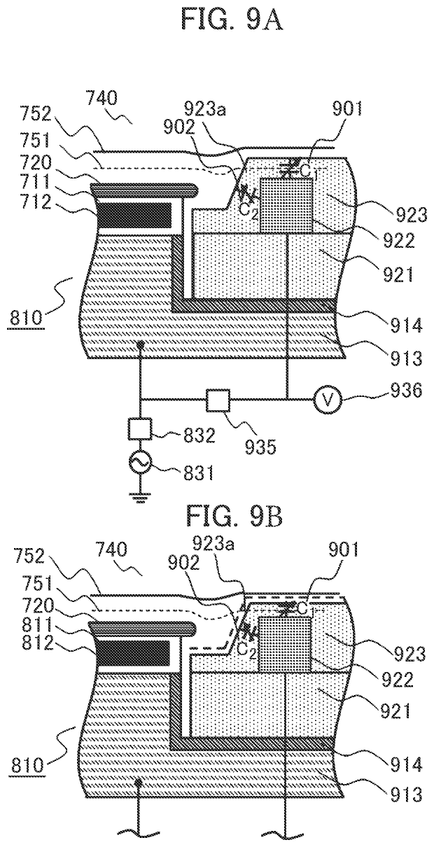

FIGS. 9A and 9B are vertical cross-sectional views schematically showing an outline of a configuration of a sample deck related to another prior art. FIG. 9A shows a conductor ring 922 and a dielectric cover ring 923 over the recessed part surrounding the outer periphery of the projected part of the base material 813 of the sample deck 810, the conductor ring 922 surrounding the outer peripheral edge of the wafer 720, the dielectric cover ring 923 being disposed to cover the upper surface and the inner and outer peripheral side wall surfaces of the conductor ring 922 and being made of ceramics or a dielectric body such as quarts. Also, such configuration is included that the impedance value between the conductor ring 922 and the plasma 740 on an equivalent circuit between the second high frequency power source 831 and the plasma 740 and the change thereof are detected, and ablation of a portion of the dielectric cover ring 923 facing the plasma 740 is detected.

The sample deck 810 of the present drawing has a function of detecting impedance related to the high frequency power on the power feeding passage between the matching device 832 and the conductor ring 922 by an impedance detector 936 electrically connected to the power feeding passage, adjusting the operation of a load impedance regulator 935 on the power feeding passage according to the detection result, and thereby adjusting the power applied to the conductor ring 922. In such configuration, when a member of the dielectric cover ring 923 covering the conductor ring 922 ablates as shown in FIG. 9B, the amount of change of electrostatic capacitances 301 and 302 of the dielectric cover ring 923 on the equivalent circuit can be detected as a parameter corresponding to the amount of ablation of the upper surface and the side surface on the inner side of the dielectric cover ring 923. Also, such function is provided that the magnitude of the high frequency power applied to the conductor ring 922 is adjusted matching the amount of ablation of the member having been detected, and the height position of the equipotential plane 751 of the sheath formed above the dielectric cover ring 923 covering the upper surface or the inner peripheral side wall surface of the conductor ring 922 and the inclination of the equipotential plane 751 above the outer peripheral edge part of the wafer 720 changing according to the height position are adjusted.

According to such configuration, an inner peripheral side wall surface 923a positioned to depart most from the outer peripheral edge of the wafer 720 in the horizontal direction (the left-right direction in the drawing) in the dielectric cover ring 923 is a position closest to the outer peripheral edge and is a position where the equipotential plane 751 passes through, and therefore the inner peripheral side wall surface 923a affects most the distribution in the horizontal direction of the equipotential plane 751 by ablation of the inner peripheral side wall surface 923a. However, according to the configuration of the present drawing, in an equivalent circuit between the plasma 740 and the second high frequency power source 931, the dielectric cover ring 923 is a portion functioning as an integrated electrostatic capacitance, it is hard to detect ablation of a specific portion of the inner peripheral side wall surface 923a discriminating from ablation of an ablating portion facing other plasma 740 namely the upper surface portion for example, and therefore distribution of the equipotential plane 751 could not be achieved to be precise and as desired.

As described above, according to the prior art described above, it was hard to detect ablation of a member in the vicinity of the outer peripheral edge part of the wafer 720 or ablation of a specific portion of a member exerting strongest impact on the change in the electric field on the outer peripheral edge part of the wafer 720 in particular, and to achieve distribution of the height of the equipotential plane or distribution of the electric field sufficiently precisely and as desired based on the detection result. Embodiments of the present invention solving such problem will be hereinafter explained using the drawings.

### First Embodiment

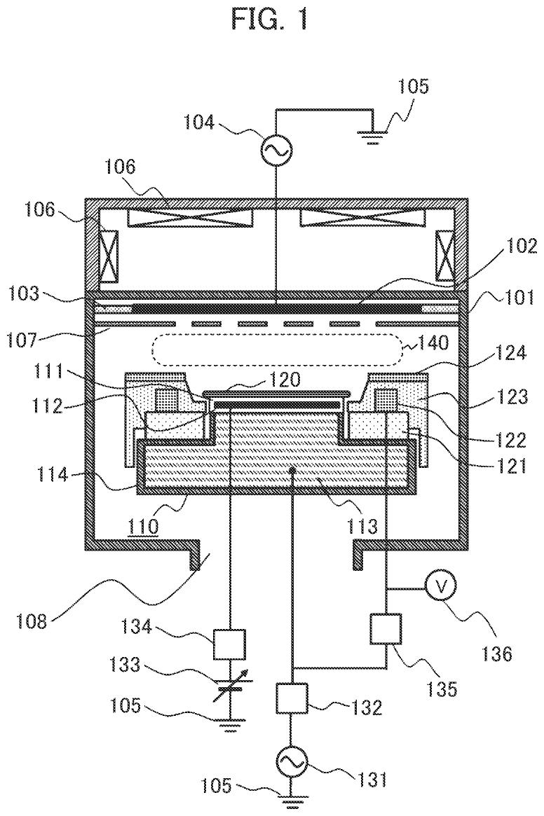

An embodiment of the present invention will be hereinafter explained using FIG. 1 to FIG. 5.

First, a summary of a plasma processing apparatus and a plasma processing method related to the present embodiment will be explained using FIG. 1. FIG. 1 is a vertical cross-sectional view schematically showing an outline of a configuration of a plasma processing apparatus related to an embodiment of the present invention.

A plasma processing apparatus of the present embodiment includes a vacuum container 101, a plasma forming unit, and an exhaust unit. The vacuum container 101 has a cylindrical shape at least in a part thereof. The plasma forming unit is disposed above the vacuum container 101 and generates an electric field or a magnetic field for forming plasma 140 inside a processing chamber which is a space inside the vacuum container 101. The exhaust unit is disposed to be connected to the vacuum container 101 below the vacuum container 101 and includes a vacuum pump such as a turbo-molecular pump that exhausts and decompresses the processing chamber inside the vacuum container 101. In the inside of the vacuum container 101, there are provided an upper electrode 102, a shower plate 107 made of a dielectric body, a sample deck 110, and vacuum exhaust port 108. The upper electrode 102 is disposed in the upper part of the vacuum container 101 and above the processing chamber and has a disk-like shape. The shower plate 107 is disposed below the upper electrode 102 to become parallel with the upper electrode 102 at an interval and has a disk shape. The sample deck 110 is disposed below the shower plate 107 and has a generally cylindrical shape. The vacuum exhaust port 108 is disposed in the bottom surface of the vacuum container 101 located below the sample deck 110, communicates with an inlet of the exhaust unit and has a circular shape. In the vacuum exhaust port 108, particles of the gas and the plasma inside the processing chamber pass through the vacuum exhaust port 108, and are discharged.

In the upper part of the vacuum container 101, a gas introduction passage is disposed. The gas introduction passage is connected to a gas introduction pipe not illustrated and allows the gas introduction pipe and a gap between the shower plate 107 and the upper electrode 102 to communicate with each other. Through the gas introduction pipe connected to a gas source, a processing gas passes through the gas introduction passage inside the vacuum container 101, flows in to the gap between the upper electrode 102 and the shower plate 107 to be diffused, and then is supplied from the upper part of the inside of the processing chamber within the vacuum container 101 through plural through holes disposed in the center part of the shower plate 107.

The upper electrode 102 is electrically connected to a first high frequency power source 104 through an electric field/radiowave passage such as a coaxial cable, the first high frequency power for forming plasma is supplied from the first high frequency power source 104, and an electric field of the first high frequency power is irradiated into the processing chamber through the upper electrode 102 and the shower plate 107. Atoms or molecules of the processing gas introduced into the processing chamber receive actions of the electric field, are excited, are disassociated or ionized, and generate the plasma 140. A magnetic field generated by two coils 106 disposed to surround the outer peripheral side and above of the side wall having a cylindrical shape in the upper part of the vacuum container 101 has magnetism symmetrically around the center axis in the vertical direction of the processing chamber, downward, and in a broadening manner inside the processing chamber, and the intensity and distribution of the plasma 140 inside the processing chamber are adjusted to those suitable to processing by the intensity and direction of the magnetic field and the distribution thereof.

Also, particles of the plasma and the processing gas inside the processing chamber are discharged to outside the processing chamber through the vacuum exhaust port 108 by operation of a vacuum exhaust means such as a turbo-molecular pump not illustrated of the exhaust unit connected through the vacuum exhaust port 108. By the balance of the flow rate or the velocity of the processing gas supplied into the processing chamber through the gas introduction port of the through hole of the shower plate 107 and the flow rate or the velocity of the particles of the gas inside the processing chamber discharged through the vacuum exhaust port 108, the inside of the processing chamber is decompressed to and maintained at a pressure of predetermined degree of vacuum suitable to each of the processing steps. Also, on the upstream side of the inlet of the turbo-molecular pump of the exhaust unit, an exhaust amount regulator not illustrated is provided, the flow rate or the velocity of the exhaust air from the vacuum exhaust port 108 is adjusted by increasing/decreasing the cross-sectional area of the flow passage for the exhaust air including the vacuum exhaust port 108.

The sample deck 110 of the present embodiment is a member having a disk or cylindrical shape, and includes a base material 113 which is a member made of metal in the inside. In the center part of the upper part of the base material 113, a cylindrical portion having a shape projected upward is provided, and the periphery of the projected part includes a recessed part that surrounds the projected part in a ring shape. The side wall and the upper surface of the recessed part excluding the upper surface of the projected part of the base material 113 of the sample deck 110 are coated by a dielectric film 114. The upper surface having a circular shape of the projected part of the base material 113 is coated by a dielectric film 111 which is a film formed by thermal spray and configured of material including a dielectric body, and configures a mounting surface in the center part of the upper surface of the projected part, the wafer 120 which is a disk-like sample of the processing object being mounted on and held by the mounting surface. The upper surface of the projected part covered by the dielectric film 111 substantially has a circular shape matching the shape of the wafer 110, and opposes the shower plate 107.

A conductor film 112 configured of a conductor material is disposed in the inside of the dielectric film 111, and is configured as an electrode having a film shape. A DC power source 133 is electrically connected to the conductor film 112 through a high frequency filter 134. The wafer 120 is electrostatically adsorbed and fixed to the upper surface of the dielectric film 111 of the sample deck 110 by DC voltage applied from the DC power source 133.

The base material 113 of the sample deck 110 functions as an electrode to which second high frequency power generated by a second high frequency power source 131 is supplied, the second high frequency power source 131 being electrically connected to the base material 113 through a matching device 132. To be more specific, when the plasma 140 is generated inside the processing chamber in a state the wafer 120 is mounted on and held by the dielectric film 111, the second high frequency power is supplied to the base material from the second high frequency power source 131, an electric field joined to the plasma 140 is generated above the upper surface of the wafer 120 by the second high frequency power, and a plasma sheath is formed between the plasma 140 and the upper surface of the wafer 120.

The plasma sheath is a region where the potential changes between the boundary face of the plasma 140 having a specific potential and the base material or the wafer 120, the base material being a conductor facing the boundary face of the plasma 140, and charged particles within the plasma 140 pass through the plasma sheath and are attracted to and collide on the upper surface of the wafer 120 according to the potential difference between the wafer 120 or the base material and the plasma. At this time, energy is imparted to the surface of a layer by collision of the charged particles. The layer has a film structure formed on the upper surface of the wafer 120 beforehand and faces the plasma, material forming the layer causes a reaction and is detached from the surface, and etching of the layer proceeds.

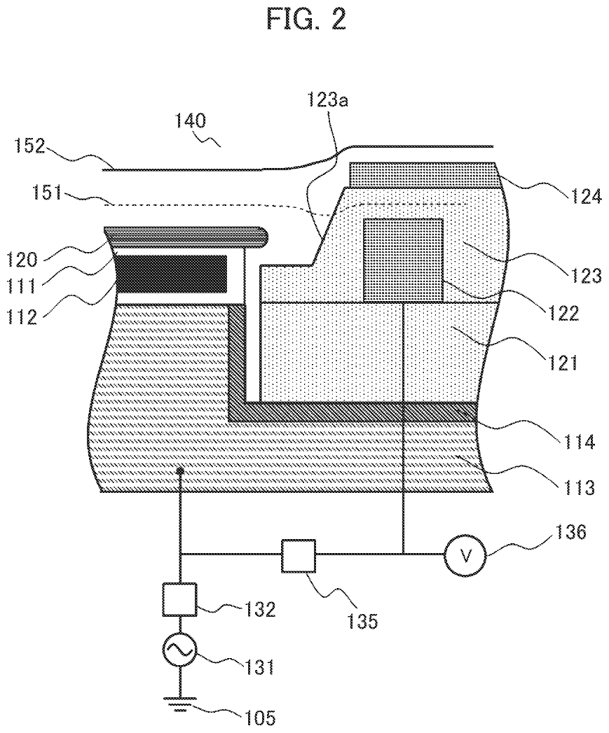

Next, detail of the configuration in the vicinity of the outer peripheral part of the sample deck 110 will be explained using FIG. 2. FIG. 2 is a vertical cross-sectional view enlargedly and schematically showing an outline of a configuration of the outer peripheral portion of the upper part of the sample deck in the plasma processing apparatus related to the embodiment shown in FIG. 1. Also, with respect to the positions marked with a reference sign same to that shown in FIG. 1, explanation thereon will be omitted unless it will be necessary.

In the present drawing, with respect to a ring-like position on the outer peripheral side of the dielectric film 111 that is the upper surface of the sample deck 110 and the wafer mounting surface, the height of the base material 113 is lowered to be recessed, and there is a step between the base material 113 or the upper surface of the dielectric film 111. In the ring-like portion on the outer peripheral side of the step namely a position above the bottom surface of the recessed part and on the outer peripheral side of the wafer 120, the dielectric film 114 is disposed, and an insulation ring 121 and a conductor ring 122 are disposed over the dielectric film 114, the insulation ring 121 being a ring-like member configured of material made of a dielectric body such as quarts and alumina for example, the conductor ring 122 being disposed above the upper surface of the insulation ring 121 and being configured of metal or a conductor material.

To the conductor ring 122, a separate line is electrically connected as a power feeding passage branching from a position between the matching device 132 and the base material on a line configuring a power feeding passage that is connected to the base material 113 from the second high frequency power source 131 through the matching device 132. On the line of the power feeding passage having been branched, a load impedance regulator 135 is disposed. The conductor ring 122 is mounted with the lower surface thereof contacting the upper surface of the insulation ring 121, and is disposed to be stored inside a ring-like recessed portion that is formed to be recessed upward from the bottom surface of a dielectric cover ring 123 made of a dielectric body such as quarts and alumina mounted above the insulation ring 121.

The inner and outer peripheral side wall surfaces and the upper surface are covered by the dielectric cover ring 123, so that the conductor ring 122 is insulated from the base material 113 which is electrically connected to the sample deck 110 or the second high frequency power source. Thus, application of high frequency power different from that to the sample deck 110 to the conductor ring 122 is allowed.

Also, the dielectric cover ring 123 having such structure that the upper surface is a flat surface is disposed to cover the inner and outer peripheral side wall surfaces and the upper surface of the conductor ring 122 and to be mounted on the insulation ring 121 and the conductor ring 122. With respect to the conductor ring 122, the upper surface and the side surface are covered by the dielectric cover ring 123 against the plasma 140 and are not exposed to the plasma 140. Therefore, metal elements configuring the conductor ring 122 are not discharged into the vacuum container 101, and metal contamination of the wafer 120 is suppressed.

With respect to a dielectric cover ring 123 of the present embodiment, the height of the ring-like portion on the inner peripheral side is lowered toward the inner peripheral side from the portion on the outer peripheral side thereof having a flat upper surface, and the vertical cross section has a tapered shape. Also, the upper surface of the innermost peripheral end part of the inner peripheral side portion is made flat in the vertical direction and is placed at a position with a small gap from the side wall having a cylindrical shape of the projected part of the sample deck 110, and is disposed so that the flat upper surface of the innermost peripheral end part is positioned below the outer peripheral edge of the wafer 120 that is in a state of being mounted on the upper surface of the dielectric film 111.

On the flat upper surface of the portion on the outer peripheral side of the dielectric cover ring 123 of the present embodiment and the upper surface including the inner peripheral end portion of the ring-like flat portion, a conductor cover ring 124 that is a member having a flat plate ring shape configured of a conductor material of Si or SiC is mounted. According to the present embodiment, the conductor cover ring 124 is disposed above the upper surface of the conductor ring 122, and the projection plane as seen from above thereof has the size and shape covering at least the entire conductor ring 122. Also, a portion on the outer peripheral side of the conductor cover ring 124 may include a portion having a cylindrical shape extending downward to cover the side wall surface of the outer periphery of the dielectric cover ring 123.

By configuring the dielectric cover ring 123 and the conductor cover ring 124 to be detachable from each other, when either one of them is consumed, it is possible to replace the ablating one only. Also, when the dielectric cover ring 123 and the conductor cover ring 124 are adhered to each other by an adhesive agent and the like, thermal conductivity between these members improves, and excessive temperature rise of one member during processing can be suppressed. Whether the both parties are to be detachable or to be adhered can be selected by a user according to the desired effect.

The magnitude of the power applied to the wafer 120 (wafer power) and the power applied to the conductor ring 122 (edge power) is adjusted by the load impedance regulator 135 that is a circuit disposed on the power feeding passage branched and connected to the conductor ring 122. According to the present embodiment, the ratio of the magnitude of the power of them and the magnitude of the power generated by the second high frequency power source 131 are adjusted by increasing/decreasing the circuit constant of the load impedance regulator 135, and thereby the magnitude of the edge power is changed to a desired one while substantially keeping the wafer power to a value within a predetermined permissible range.

Also, onto the power feeding passage having been branched, an impedance detector 136 for measuring the magnitude of the impedance may be connected. The impedance detector 136 is disposed to be electrically connected to a position on the power feeding passage between the load impedance regulator 135 and the conductor ring 122, and detects any one or plural numbers out of the current value of the high frequency power applied to the conductor ring 122, DC voltage value, or peak-to-peak voltage (Vpp) value. A case of detecting the change in the impedance of a position on the power feeding passage using the Vpp value will be hereinafter described. The Vpp value having been detected is stored in a storage medium and the like not illustrated, and a user of the apparatus can confirm this value from an interface for management and operation of the apparatus not illustrated. Such detector may be disposed inside the load impedance regulator 135 as a specific circuit or element.

At the time of processing the plasma, potential difference (bias potential) occurs between the wafer 120 and the plasma 140, and an electric field is formed above the wafer 120 by the wafer power, and an electric field is formed above the wafer 120. In a similar manner, by the edge power, an electric field is formed above the dielectric cover ring 123 and the conductor cover ring 124 through the dielectric cover ring 123 or through both of the dielectric cover ring 123 and the conductor cover ring 124. The edge power is controlled so that an equipotential plane 151 within the plasma sheath becomes parallel with the upper surface of the wafer 120 in a space of the processing chamber above a portion on the outer peripheral side of the wafer 120. Thus, inclination of the shape (tilting) after etching of the upper surface of the portion on the outer peripheral side of the wafer 120 is suppressed.

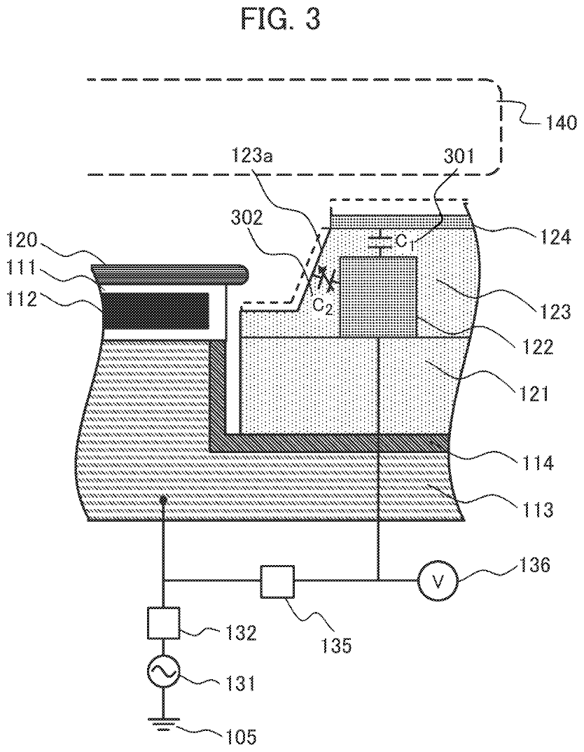

Next, the change of the state in the vicinity of the outer peripheral part of the wafer after repeating the plasma processing and allowing a member in the vicinity of the outer peripheral part of the wafer to ablate will be explained using FIG. 3. FIG. 3 is a vertical cross-sectional view schematically showing an outline of a configuration of the embodiment shown in FIG. 2 in a state a member on the outer peripheral portion of the upper part of the sample deck ablates.

A portion that ablates by plasma processing is mainly a portion 123a covering the upper surface of the conductor cover ring 124 and the inner side surface of the conductor ring 122 of the dielectric cover ring 123, the portion 123a being a position facing the plasma 140. Ablation of the inner side surface 123a that is the upper surface of the tapered portion of the portion on the inner peripheral side and the flat inner peripheral end edge portion of the dielectric cover ring close to the wafer 120 affects distribution of the height of the equipotential plane 151 over the upper surface of the portion on the outer peripheral side of the wafer 120. Therefore, the effect of ablation of the conductor cover ring 124 is suppressed, and ablation of the inner side surface 123a is detected.

Here, on a circuit for supplying the edge power, an impedance component in a portion between the load impedance regulator 135 and the plasma 140 will be focused. The edge power whose magnitude is controlled through the load impedance regulator 135 is electrically coupled to the plasma 140 through the conductor ring 122, the dielectric cover ring 123, and the conductor cover ring 124 in this order.

On an equivalent circuit expressing electric coupling with the second high frequency power source 131 coupled with the plasma 140, since the conductor ring 122 and the conductor cover ring 124 are conductors, they do not express themselves as an impedance component. That is to say, even when the conductor cover ring 124 may ablate, the impedance component of this circuit does not change.

On the other hand, it can be considered that the portions of the dielectric material of the dielectric cover ring 123 between the upper surface and the inner side surface of the dielectric cover ring 123 and the surface of the conductor ring 122 disposed to be stored in the inside configure the electrostatic capacitances 301 and 302 respectively. Also, ablation of the inner side surface 123a of the dielectric cover ring makes the impedance component be changed as the increase of the electrostatic capacitance 302. From this fact, it is considered that the amount of ablation of the portion of the inner side surface 123a of the dielectric cover ring 123 can be detected while suppressing the effect of ablation of the conductor cover ring 124 by detecting the change in impedance in the circuit for supplying the edge power.

A configuration for detecting ablation of the inner side surface 123a of the dielectric cover ring 123 in the present embodiment will be hereinafter explained. First, before occurrence of ablation of the member made of a dielectric body of the dielectric cover ring 123, or, in concrete terms, after the dielectric cover ring 123 is disposed inside the processing chamber and before processing of the wafer 120 for manufacturing a semiconductor device for the first product is started, another wafer 120 having the same structure as the wafer 120 for the product is processed using the plasma 140 with the condition for processing the wafer 120 for the product, and a Vpp value of an initial stage when an optional dielectric cover ring 123 has been started to be used is measured using the impedance detector 136 that is connected to a circuit for supplying the edge power. As described above, it is preferable that the condition for processing the wafer 120 at this time (the standard processing condition) is same to the condition for processing the wafer 120 for an actual product (the actual processing condition), or it is preferable that at least the wafer power and the edge power are same to those of the actual processing condition. The Vpp value of the initial stage having been detected is stored in a storage device such as a storage medium not illustrated.

After detecting the Vpp value of the initial stage, the wafer 120 for the product is processed by the actual processing condition. Accompanying processing of plural number of sheets of the wafer 120, the inner side surface 123a of the dielectric cover ring 123 ablates, and the thickness of the member configured of the material of a dielectric body of the dielectric cover ring 123 between the surface of the conductor cover ring 122 to which the power from the second high frequency power source is supplied and the inner side surface 123a facing the plasma 140 inside the processing chamber decreases. Thus, the electrostatic capacitance 302 on the equivalent circuit of a portion of the dielectric cover ring 123 passing through the inner side surface 123a changes (increases in general), and the impedance changes.

After completion of processing of the wafer 120, another wafer 120 having a structure same to that of the wafer 120 for the product is processed again by the standard processing condition, and the Vpp value at the time of ablation of this time is measured. At this time, since impedance of the circuit lowers by increase of the electrostatic capacitance 302, the Vpp value at the time of ablation increases. From the difference between Vpp at the time of ablation and the Vpp value of the initial stage, the change amount of the electrostatic capacitance 302 in the circuit is calculated. When the amount of ablation and the material of the member between the inner side surface 123a of the dielectric cover ring 123 and the surface of the conductor ring 122 can be deemed to be equal with respect to the direction of the surface thereof, the ablation amount is detected from the value of Vpp (and the difference thereof), the dielectric constant of the material, the area of the inner side surface 123a, and so on. Also, using the amount of ablation of the inner side surface 123a of the dielectric cover ring 123 having been detected, estimation of the progress of ablation of the dielectric cover ring 123 and estimation of the timing for replacement thereof can be performed more precisely. Further, by accurately adjusting the amount of the second high frequency power supplied to the conductor ring 122 by operation of the load impedance regulator 135 using the amount of change of Vpp, dispersion of tilting of the processing shape in the vicinity of the outer peripheral edge part of the wafer 120 can be reduced, and the yield or the efficiency of processing can be improved.

That is to say, when the inner side surface 123a of the dielectric cover ring 123 ablates, the Vpp value by the standard processing condition changes. Also, distribution of the height and the shape in the radial direction and the peripheral direction of the wafer 120 of the equipotential plane 151 within the plasma sheath formed above the wafer 120 and the upper surface of the dielectric cover ring 123 change, and, by the effect of this change, the shape of the equipotential plane 151 above the upper surface of the outer peripheral part of the wafer 120 and tilting of the etching shape worked by an action of the charged particles made to be incident perpendicularly to the equipotential plane 151 and colliding on the surface of the film formed beforehand on the upper surface of the wafer 120 change. Therefore, it is liable that tilting of the shape of the surface of the wafer 120 exceeds the permissible value as ablation of the dielectric cover ring 123 proceeds.

According to the present embodiment, in order to maintain such tilting within a permissible range, the edge power is adjusted appropriately. First, a change amount ΔVpp_lim between the value of Vpp with which tilting of the etching shape corresponds to the upper limit value or the lower limit value of the permissible range accompanying progress of ablation and the value of Vpp of the initial stage is detected by processing the wafer 120 that is equivalent to one for the product beforehand. Also, the edge power value that can achieve the shape of the equipotential plane 151 that makes the tilting amount corresponding to the value of Vpp changing accompanying change of the height (thickness) caused by ablation of the inner side surface 123a of the dielectric cover ring 123 or the amount of the change to be 0 is also obtained beforehand. The condition of processing of the wafer 120 at the time of such detection is one that is same to the standard processing condition described above or one that can be deemed to be same to the standard processing condition described above.

When ablation of the dielectric cover ring 123 proceeds and an event that the change amount of the Vpp value by the standard processing condition becomes equal to or larger than ΔVpp set that is a value smaller than ΔVpp_lim having been set beforehand is detected from an output from the impedance detector 136, using the relation between the value of Vpp accompanying ablation of the inner side surface 123a of the dielectric cover ring 123 and the amount of the change thereof and the edge power achieving optimum tilting obtained beforehand, the magnitude of the edge power supplied to the conductor ring 122 is changed to a value that can achieve the etching shape of the initial stage. According to the present embodiment, the output of the second high frequency power source 131 or the constant of the circuit of the load impedance regulator 135 is adjusted so that the edge power with which tilting becomes 0 corresponding to the electrostatic capacitance of the dielectric cover ring 123 that ablated is supplied to the conductor ring 122.

Thus, it is adjusted so that the height position of the equipotential plane 151 above the upper surface of the outer peripheral part of the wafer 120 and above the upper surface of the dielectric cover ring 123 becomes horizontal with respect to the radial direction of the wafer 120, and it is adjusted so that the tilting becomes constant among plural number of sheets of the wafer 120 according to increase of the number of sheets of the wafer 120 to be processed and the change of the value of the thickness (electrostatic capacitance) of the member of the dielectric cover ring 123 abating accompanying the increase. As a result, tilting of the shape after processing of the wafer 120 is made within a permissible range over a long period of time, dispersion of the shape is suppressed, and the yield of the processing improves.

Also, the timing of replacement by ablation of the dielectric cover ring 123 can be estimated with high accuracy from the change of impedance on the power feeding passage. That is to say, the Vpp value of the limit of the case ablation of the inner side surface 123a of the dielectric cover ring 123 proceeds, the amount of change of Vpp reaches ΔVpp_lim, and replacement becomes necessary in a case the wafer 120 having an optional structure is processed by a predetermined condition is obtained beforehand, and the timing of detection of an event that the value of Vpp by the standard processing condition exceeds the Vpp value of the limit can be used as the timing the dielectric cover ring 123 should be replaced. Furthermore, by provision of a function of notifying an event that the value of Vpp detected by the impedance detector 136 comes close to the limit Vpp value namely the replacement timing is close from an alarm unit not illustrated and provided in the plasma processing apparatus, or displaying a warning or notification on a monitor of CRT and liquid crystal for example, it is possible to promote a user of the apparatus to replace the member.

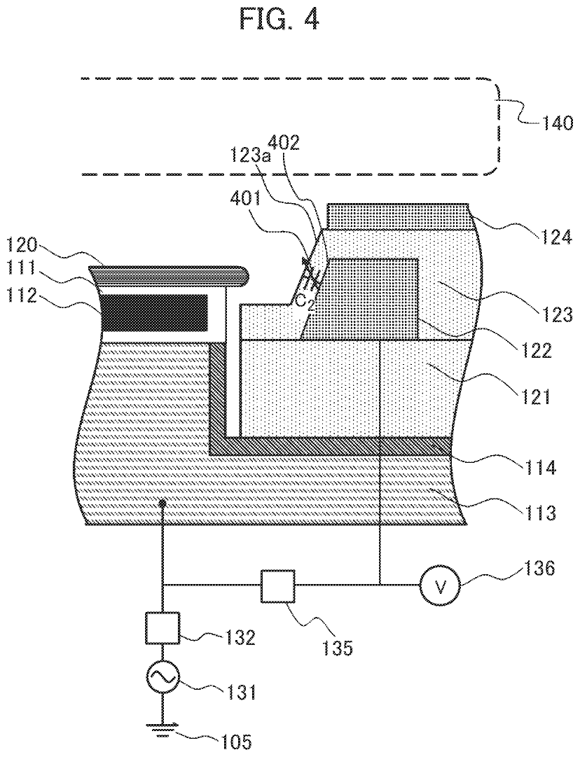

A modified example capable of more precisely detecting ablation of a member of the dielectric cover ring 123 is shown in FIG. 4. FIG. 4 is a vertical cross-sectional view schematically showing an outline of a configuration of the outer peripheral part of the sample deck of a modified example of the plasma processing apparatus related to the embodiment shown in FIG. 2.

In the present example, the shape of the conductor ring 122 is configured so that an inner side surface 402 thereof becomes parallel with the inner side surface 123a of the dielectric cover ring 123, and other configurations are made to be equal to those of the first embodiment. In this modified example, the inner side surface of the conductor ring 122 has a shape of including an inclined surface with the thickness being enlarged toward the outside so as to become parallel with the inner side surface 123a that is the upper surface of the inner peripheral side portion where the cross section of the dielectric cover ring 123 has a tapered shape. Also, it is possible to make the average of the thickness of the inner side surface 123a of the dielectric cover ring 123 small and to enlarge an electrostatic capacitance 401 of a member made of a dielectric body of the dielectric cover ring 123 configuring the inner side surface 123a. Thus, impedance change accompanying ablation of the member also becomes large, and the ablation amount of the member can be detected more precisely.

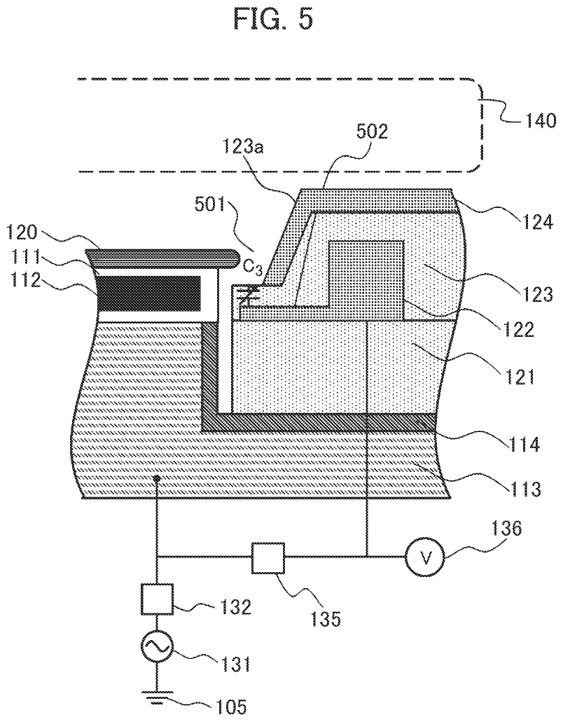

Also, by applying the embodiment and the modified example described above and devising the shape of the conductor ring 122 and the conductor cover ring 124, the portion whose ablation is detected can be limited optionally. FIG. 5 is a vertical cross-sectional view schematically showing an outline of a configuration of the outer peripheral part of a sample deck of another modified example of the plasma processing apparatus related to the embodiment shown in FIG. 2.

According to the present example, a flange part 502 is provided where the lower part of the inner peripheral side wall of the conductor ring 122 shown in FIG. 2 is extended in a flange shape to the inner peripheral side, and the conductor ring 122 has such shape that the flange part 502 extends below a range starting from the inner side surface 123a to the inner peripheral edge part where the upper surface of the dielectric cover ring 123 is flat below the dielectric cover ring 123 that is disposed to cover the conductor ring 122. Also, the conductor cover ring 124 covers not only the flat upper surface of the portion on the outer peripheral side of the dielectric cover ring 123 but also all of the inner side surface 123a that is the upper surface of the tapered shape of the portion on the inner peripheral side, and the inner peripheral edge part of the conductor cover ring 124 extends to reach the flat upper surface of the inner peripheral edge part of the dielectric cover ring 123.

In the present example, out of the dielectric cover ring 123, with respect to a portion covered by the conductor cover ring 124 namely the upper surface of the portion on the outer peripheral side and the inner side surface 123a, ablation is suppressed and the change of impedance by the electrostatic capacitance of the member of the dielectric cover ring 123 between these portions and the upper surface of the conductor ring 122 is suppressed. On the other hand, ablation of a portion not covered by the conductor cover ring 124 namely the inner peripheral edge part of the dielectric cover ring 123 is detected based on the change of Vpp by the impedance detector 135 as the change of an electrostatic capacitance 501.

According to the present example, since ablation of the inner peripheral edge part of the dielectric cover ring 123 proceeds largely compared to other positions accompanying increase of the time for processing of the wafer 120 using the plasma 140 or the number of sheets of the wafer 120 having been processed, the ablation is detected by the impedance detector 136 as the change of Vpp. The amount of ablation of a specific position of the dielectric cover ring 123 is detected precisely suppressing the effect of ablation of other positions, and the timing for replacement of the dielectric cover ring 123 can be estimated more precisely. Also, since preciseness of detection of the ablation amount and the value of Vpp corresponding thereto as well as the amount of change thereof are improved, in the plasma processing apparatus of the present example where the height position of the equipotential plane 151 above the upper surface of the outer peripheral part of the wafer 120 and above the upper surface of the dielectric cover ring 123 is made horizontal with respect to the radial direction of the wafer 120 and tilting is adjusted to be constant among plural number of sheets of the wafer 120 according to increase of the number of sheets of the wafer 120 to be processed and the change of the value of the thickness (electrostatic capacitance) of the member of the dielectric cover ring 123 which abates accompanying the increase of the number of sheets of the wafer 120 to be processed, tilting of the shape after processing of the wafer 120 is made to be within a permissible range for a long period of time, dispersion of the shape is suppressed, and the yield of processing improves.

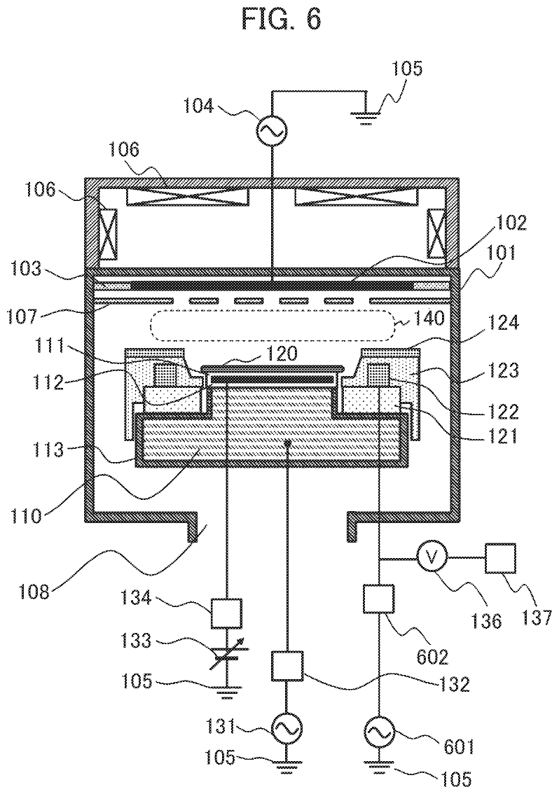

The action and the effect of the examples described above can be obtained also in a configuration of supplying each of the wafer power and the edge power by independent power sources. FIG. 6 is a vertical cross-sectional view schematically showing an outline of a configuration of a plasma processing apparatus related to a still other modified example of the embodiment shown in FIG. 1. In the present drawing also, explanation on the positions marked with a reference sign same to that of the embodiment shown in FIG. 1 will be omitted unless it will be necessary.

According to the present modified example, as shown in FIG. 6, the second high frequency power source 131 is not connected to the conductor ring 122, and an independent third high frequency power source 601 is connected through a matching device 602. When this configuration is used, it is allowed to change the frequency of the wafer power and the edge power, or to equalize the frequency of the wafer power and the edge power and to synchronize the phase of the power outputted by each thereof or to adjust the phase of the power outputted by each thereof to have a phase difference of a predetermined value. Further, it is also possible to replace the third high frequency power source 601 by a DC power source and to apply DC power to the edge power.

In the example described above, it was described that the material of the conductor cover ring 124 was Si or SiC. This is based on a viewpoint of preventing metal contamination in processing a semiconductor device in particular. However, it is easily presumed that, when consideration on metal contamination is not necessary, an effect similar to that of the embodiments described above is secured even when metal material such as aluminum is used for example.

Further, although plasma processing using an aspect of a parallel flat plate type plasma processing apparatus was exemplified in the present embodiments, the effect of the present invention is not limited by the plasma generating method in plasma processing. For example, even in an induction coupling type plasma processing apparatus and an ECR resonance type plasma processing apparatus, or even in a parallel flat plate type plasma processing apparatus including a mechanism that is different from that of the present embodiments, a similar effect is secured by the configuration in the vicinity of the outer peripheral part of the sample deck similar to that of the present invention.

### LIST OF REFERENCE SIGNS

101 . . . Vacuum container

102 . . . Upper electrode

103 . . . Insulation ring

104 . . . First high frequency power source

105 . . . Ground

106 . . . Coil

107 . . . Shower plate

108 . . . Vacuum exhaust port

110 . . . Sample deck

111 . . . Dielectric film

112 . . . Conductor film

113 . . . Dielectric film

120 . . . Wafer

121 . . . Insulation ring

122 . . . Conductor ring

123 . . . Dielectric cover ring

123a . . . Inner side surface

124 . . . Conductor cover ring

131 . . . Second high frequency power source

132 . . . Matching device

133 . . . DC power source

134 . . . High frequency filter

135 . . . Load impedance regulator

136 . . . Impedance detector

140 . . . Plasma

151 . . . Equipotential plane

152 . . . Sheath boundary face

1. A plasma processing apparatus, comprising:
a processing chamber in which plasma is generated, the processing chamber being disposed inside a vacuum container;
a sample deck on which a wafer of an object of processing using the plasma is mounted, the sample deck being disposed in a lower part inside the processing chamber, the wafer being mounted on an upper surface of a projected part disposed at a center part of an upper part of the sample deck;
an electrode that is supplied with high frequency power during processing of the wafer, the electrode being disposed inside the sample deck;
a ring-like member made of a conductor disposed to surround the upper surface on an outer peripheral side of the projected part of the sample deck;
a first ring-like cover made of a dielectric body disposed to oppose and cover the ring-like member between the ring-like member and the processing chamber and between the ring-like member and an upper surface of the sample deck;
a second ring-like cover made of a conductor disposed to cover the first ring-like cover between the processing chamber and an upper surface of the first ring-like cover; and
a controller that adjusts magnitude of high frequency power according to a result of detection of voltage of the high frequency power flowing through a power feeding passage that connects a high frequency power source and the ring-like member to each other, the high frequency power source supplying high frequency power to the ring-like member made of a conductor during processing of the wafer.

2. The plasma processing apparatus according to claim 1,
wherein a surface of a portion on the inner peripheral side of the ring-like member made of a conductor is covered by a member made of a dielectric body which covers the ring-like member against the plasma, between the ring-like member and the projected part of the sample deck, and a surface of a portion on the inner peripheral side of the member made of a dielectric body and facing the plasma and a surface of a portion on the inner peripheral side of the ring-like member are disposed to be parallel to each other.

3. The plasma processing apparatus according to claim 2,
wherein the member made of a dielectric body covering a portion on the inner peripheral side of the ring-like member is configured to be integral with the first ring-like cover.

4. The plasma processing apparatus according to claim 1,
wherein a portion on the inner peripheral side of the member made of a dielectric body covering a portion on the inner peripheral side of the ring-like member has the surface that is positioned between the ring-like member made of a conductor and the film-like electrode, the surface inclining with the height being elevated toward the outer peripheral side to increase thickness in the vertical direction of the member made of a dielectric body, and the second ring-like cover is disposed on an upper surface on the outer peripheral side of the inclined surface to cover the inclined surface.

5. The plasma processing apparatus according to claim 1,
wherein an upper surface of the ring-like member made of a conductor is disposed at a position higher than an upper surface of the sample deck.

6. The plasma processing apparatus according to claim 1, further comprising:
a third ring-like member that is disposed below the ring-like member made of a conductor and between the ring-like member made of a conductor and an electrode inside the sample deck, and insulates the ring-like member made of a conductor and the electrode inside the sample deck.
